(19) United States
(12) Patent Application Publication
(10) Pub. No.: US 2023/0262935 A1
(43) Pub. Date: Aug. 17, 2023

(54) HEAT DISSIPATION DEVICE AND ANTI-VIBRATION HEAT CONDUCTION STRUCTURE THEREOF

(71) Applicant: CELSIA TECHNOLOGIES TAIWAN, INC., Taoyuan City (TW)

(72) Inventors: George A. Meyer, IV, Morgan Hill, CA (US); Chien-Hung SUN, Taoyuan City (TW)

(21) Appl. No.: 17/584,459

(22) Filed: Jan. 26, 2022

(51) Int. Cl. H05K 7/20

(52) U.S. Cl. CPC H05K 7/2039

(57) ABSTRACT

This disclosure provides a heat conduction structure and a heat dissipation device. The heat dissipation device includes the heat conduction structure and a heat conductor. The heat-absorbing side of the heat conducting base is recessed with an accommodating slot. The heat diffusion plate is movably disposed in the accommodating slot and includes an inner conducting surface, an outer conducting surface, and an anti-vibration surface. The anti-vibration surface is connected to the inner conducting surface and the outer conducting surface, and a lateral gap is reserved between the anti-vibration surface and an inner wall surface of the accommodating slot. The thermal interface material is filled in the lateral gap to have the anti-vibration effect and avoid damage caused by an external vibration for maintaining the normal operation and reliability of the system.

### BACKGROUND OF THE DISCLOSURE

### Technical Field

The technical field relates to a heat conduction structure, and more particularly relates to an anti-vibration heat conduction structure.

### Description of Related Art

With the rapid development of the computer industry, heated electronic components such as microprocessor chips may generate a lot of heat during operation. If the heated electronic components or semiconductor components are not cooled in time, the electronic components may be damaged or the service life may be shortened. In this regard, most electronic products usually have heat sinks installed inside for cooling heated electronic components.

Particularly, in some special systems such as industrial computers or military computers, electronic components such as microprocessor chips usually require a more stable operating environment and heat dissipation performance to avoid external vibration that affects the operation of the internal electronic circuits inside the computers or damage due to overheating, so as to maintain the normal operation and reliability of the system and to extend the service life.

In view of the above drawbacks, the inventor proposes this disclosure based on his expert knowledge and elaborate researches in order to solve the problems of related art.

### SUMMARY OF THE DISCLOSURE

One object of this disclosure is to provide a heat dissipation device and an anti-vibration heat conduction structure thereof, in which the heat diffusion plate and the heat conducting base are prevented from collision through the arrangement of thermal interface material under an action of an external force. As a result, the heat conduction structure has the anti-vibration effect to avoid damage caused by an external vibration and further maintains the normal operation and reliability of the system.

In order to achieve the object mentioned above, this disclosure provides an anti-vibration heat conduction structure including a heat conducting base, a heat diffusion plate and a thermal interface material. The heat conducting base includes a heat-absorbing side and a heat-emitting side opposite to each other, and the heat-absorbing side is recessed with an accommodating slot. The heat diffusion plate is movably disposed in the accommodating slot. The heat diffusion plate includes an inner conducting surface thermally connected to the heat conducting base, an outer conducting surface thermally connected to a heating element and at least one anti-vibration surface. The at least one anti-vibration surface is respectively connected to the inner conducting surface and the outer conducting surface, and a lateral gap is reserved between the anti-vibration surface and an inner wall surface of the accommodating slot. The thermal interface material is filled in the lateral gap between the at least one anti-vibration surface and the accommodating slot. The thermal interface material is filled in the lateral gap between the at least one anti-vibration surface and the accommodating slot. The heat diffusion plate and the heat conducting base are prevented from collision through the arrangement of thermal interface material under an action of an external force.

In order to achieve the object mentioned above, this disclosure provides a heat dissipation device including the anti-vibration heat conduction structure and a heat conductor. The heat conductor is thermally connected to the heat-emitting side and combined with the heat conducting base.

Comparing with the related art, the heat conducting base of the heat conduction structure in this disclosure is recessed with an accommodating slot, and the heat diffusion plate is disposed with anti-vibration surfaces. Additionally, a lateral gap is reserved between the anti-vibration surface and the inner wall surface of the accommodating slot, and the thermal interface material is filled in the lateral gap. As a result, the heat diffusion plate and the heat conducting base are prevented from collision through the arrangement of thermal interface material under an action of an external force to have the anti-vibration effect. Furthermore, since the thermal interface material may reduce the thermal resistance between the heat diffusion plate and the heat conducting base, the heat conducted to the heat diffusion plate is effectively transferred to the heat conducting base to be dissipated for heat dissipation.

### BRIEF DESCRIPTION OF DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a cross sectional view of the heat dissipation device with the anti-vibration heat conduction structure in this disclosure.

FIG. 2 is a top schematic view of the heat dissipation device with the anti-vibration heat conduction structure in this disclosure.

FIG. 3 is an application schematic view of the heat dissipation device with the anti-vibration heat conduction structure in this disclosure.

FIG. 4 is a cross sectional view of another embodiment of the heat dissipation device with the anti-vibration heat conduction structure in this disclosure.

FIG. 5 is a top schematic view of another embodiment of the heat dissipation device with the anti-vibration heat conduction structure in this disclosure.

FIG. 6 is an application schematic view of another embodiment of the heat dissipation device with the anti-vibration heat conduction structure in this disclosure.

FIG. 7 is a cross sectional view of a still another embodiment of the heat dissipation device with the anti-vibration heat conduction structure in this disclosure.

FIG. 8 and FIG. 9 are cross sectional views of another embodiment of the heat dissipation device with the anti-vibration heat conduction structure in this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

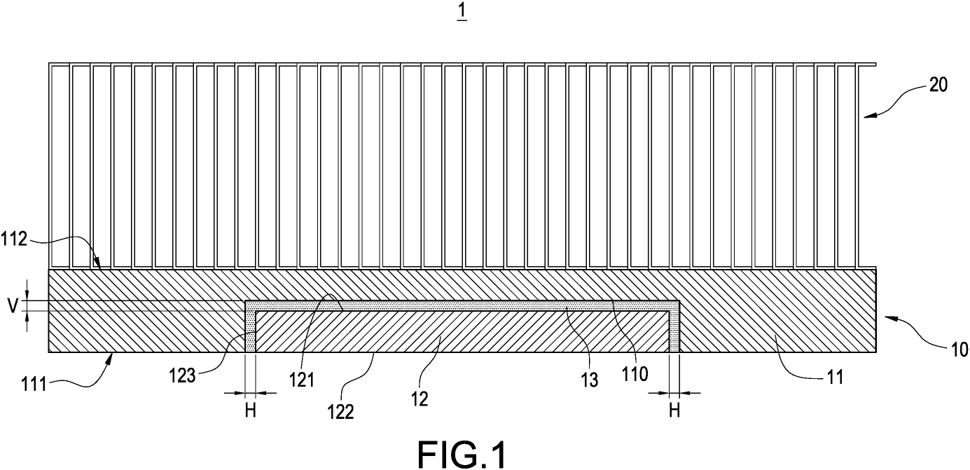

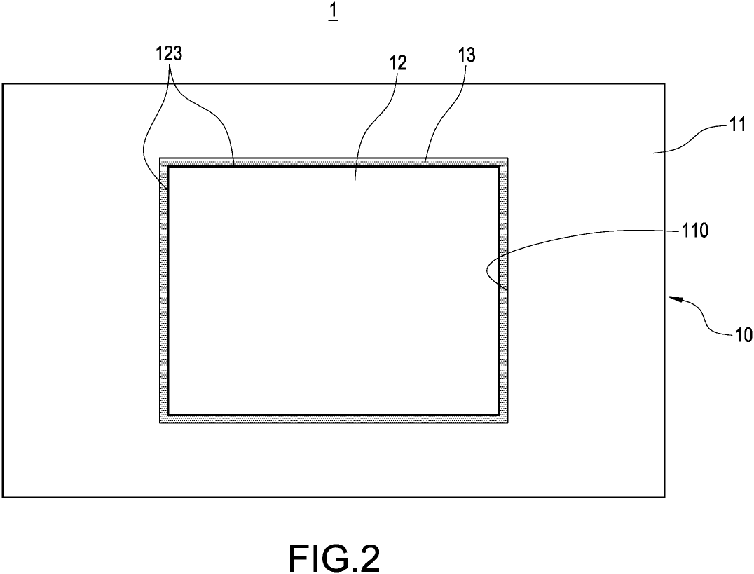

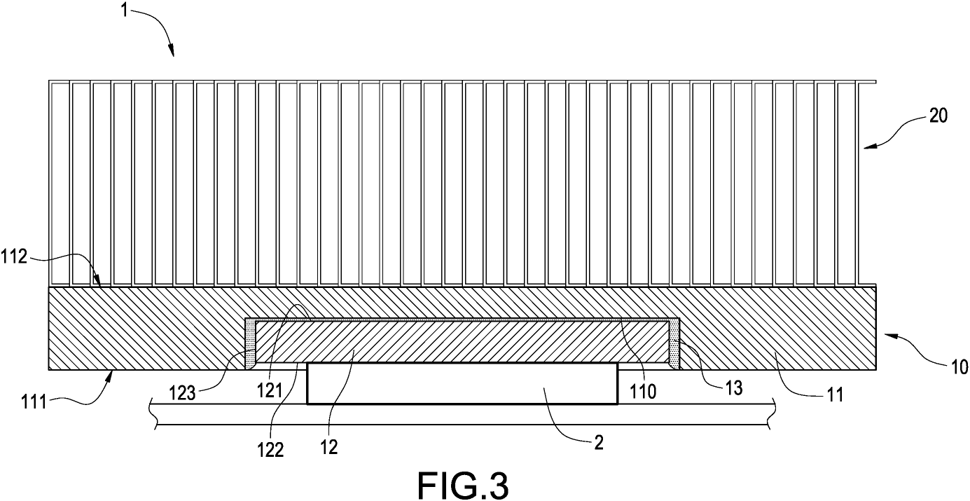

Please refer to FIG. 1 to FIG. 3, which respectively depict a cross sectional view, a top schematic view and an application schematic view of the heat dissipation device with the anti-vibration heat conduction structure in this disclosure. This disclosure is a heat dissipation device 1 including an anti-vibration heat conduction structure 10 and a heat conductor 20. The heat conduction structure 10 includes a heat conducting base 11, a heat diffusion plate 12 and a thermal interface material 13. The heat conductor 20 is combined with the heat conduction structure 10 to constitute the heat dissipation device 1 for dissipating the heat of a heated element 2. It should be noted that the heated element 2 is not particularly limited. The heated element 2 may include an electronic component such as a central processing unit (CPU), a microprocessor unit (MPU), or a graphics processing unit (GPU), etc.

The heat conducting base 11 includes a heat-absorbing side 111 and a heat-emitting side 112 opposite to each other, and the heat-absorbing side 111 is recessed with an accommodating slot 110. Additionally, the heat conductor 20 is thermally connected to the heat-emitting side 112 and combined with the heat conducting base 11.

The heat diffusion plate 12 is movably disposed in the accommodating slot 110. Furthermore, the heat diffusion plate 12 includes an inner conducting surface 121 thermally connected to the heat conducting base 11, an outer conducting surface 122 thermally connected to the heating element 2 and at least one anti-vibration surface 123. The anti-vibration surface 123 is respectively connected to the inner conducting surface 121 and the outer conducting surface 122, and a lateral gap H is reserved between the anti-vibration surface 123 and an inner wall surface of the accommodating slot 110.

Specifically, the heat conducting base 11 and the heat diffusion plate 12 are heat conduction structures, which are respectively composed of a solid copper plate, a solid aluminum plate, a vapor chamber or a flat heat pipe.

Moreover, the thermal interface material 13 is filled in the lateral gap H between the anti-vibration surface 123 and the accommodating slot 110. As a result, by the arrangement of thermal interface material 13 therebetween, the heat diffusion plate 12 and the heat conducting base 11 are prevented from collision under an action of an external force. That is, the diffusion plate 12 and the heat conducting base 11 are free from contacting each other through the thermal interface material 13 under the external force.

In other words, when the external force acts on the heat diffusion plate 12 or the heat conducting base 11 which leads to the relative displacement between the heat diffusion plate 12 and the heat conducting base 11, the thermal interface material 13 may act like a buffer between the heat diffusion plate 12 and the heat conducting base 11. Accordingly, when the heat conduction structure 10 is subjected to an external force, though the heat diffusion plate 12 and the heat conducting base 11 have relative displacement therebetween, the heating element 2 may not be affected. Therefore, the heat conduction structure 10 has the anti-vibration effect to avoid damage caused by an external vibration and further maintains the normal operation and reliability of the heated element 2.

It should be noted that the thermal interface material 13 has desirable thermal conductivity, and may be such as a thermal conductive paste or a thermal conductive silicone, etc., to reduce the thermal resistance between the heat diffusion plate 12 and the heat conducting base 11. Therefore, the heat of the heated element 2 is conducted to the thermal diffusion plate 12 and then effectively transmitted to the heat conducting base 11 through the thermal interface material 13.

Accordingly, the heat generated by the heated element 2 during the operation is conducted to the heat diffusion plate 12 and then transmitted to the heat conducting base 11 through the thermal interface material 13. After that, the heat is conducted to the heat conductor 20 from the heat conducting base 11. Finally, the heat is dissipated from the heat conductor 20. It should be noted that implementation of the heat conductor 20 is not particularly limited, and the heat conductor 20 may include an aluminum extruded heat sink or heat dissipating fins, etc.

In one embodiment of this disclosure, a vertical gap V is reserved between the inner conducting surface 121 of the heat diffusion plate 12 and the inner wall surface of the accommodating slot 110. Moreover, the thermal interface material 13 is filled in the vertical gap V between the inner conducting surface 121 and the heat conducting base 11. Specifically, a size of the lateral gap H or the vertical gap V is about 0.5 mm to about 1.0 mm.

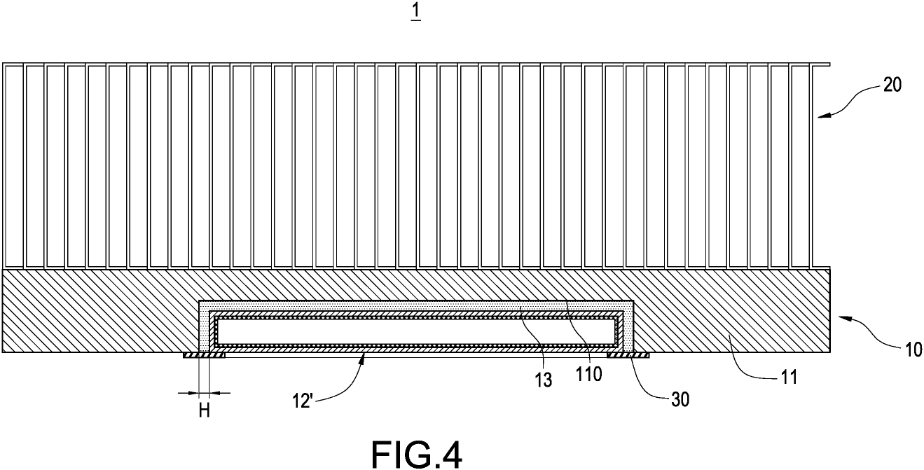

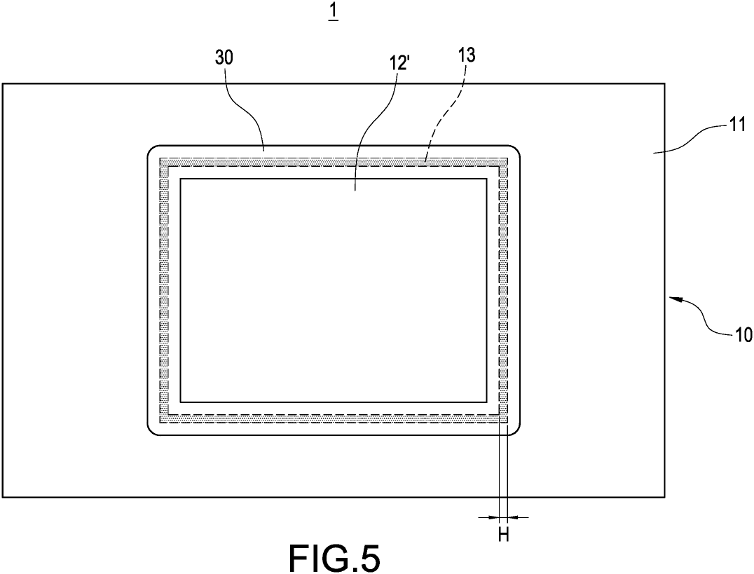

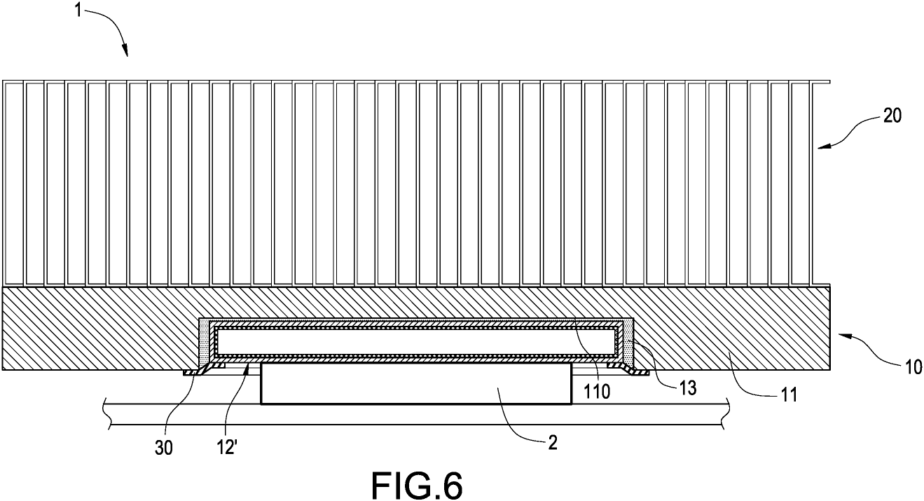

Please further refer to FIG. 4 to FIG. 6, they respectively depict a cross sectional view, a top schematic view and an application schematic view of another embodiment of the heat dissipation device with the anti-vibration heat conduction structure in this disclosure. This embodiment is similar to the previous embodiment, and the difference is that the heat conduction structure 10 in this embodiment further includes a seal ring 30. The seal ring 30 is disposed between the heat conducting base 11 and the heat diffusion plate 12′ to seal the exposed part (that is, the opening between the heat conducting base 11 and the heat diffusion plate 12′) of the lateral gap H. Additionally, the thermal diffusion plate 12′ is a vapor chamber in this embodiment.

It is worth of noticing that the seal ring 30 has flexibility. Therefore, when the heat diffusion plate 12′ or the heat conducting base 11 has relative displacement under an external force, the seal ring 30 may tightly seal the lateral gap H.

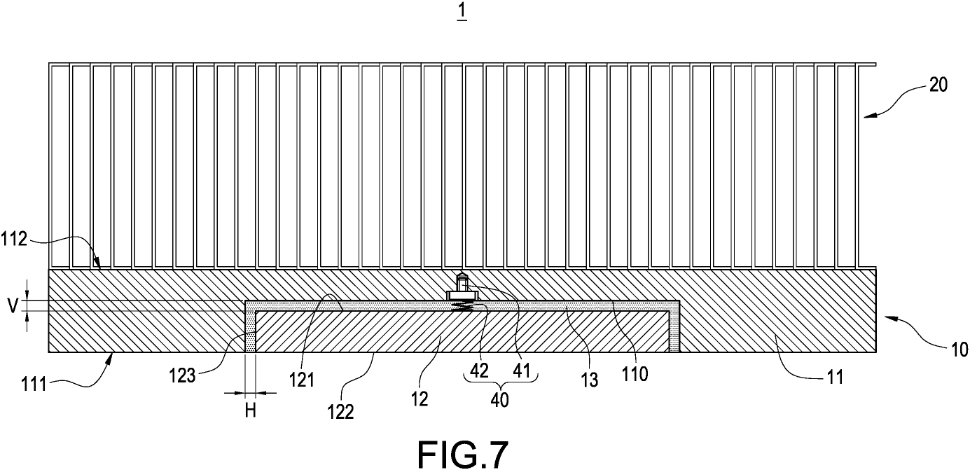

Please further refer to FIG. 7, it depicts a cross sectional view of a still another embodiment of the heat dissipation device with the anti-vibration heat conduction structure in this disclosure. This embodiment is similar to the embodiment of FIG. 1, and the difference is that the heat conduction structure 10 in this embodiment further includes an elastic element 40 connected between the heat conducting base 11 and the heat diffusion plate 12. One end of the elastic element 40 is connected to the inner wall surface of the accommodating slot 110, and the other end of the elastic element 40 is connected to the inner conducting surface 121 of the heat diffusion plate 12.

Specifically, the elastic element 40 includes a screw element 41 and a spring 42. The screw element 41 includes a screw fixed on the inner wall surface of the accommodating slot 110. One end of the spring 42 is connected to the screw element 41, and the other end of the spring 42 is welded on the inner conducting surface 121 of the heat diffusion plate 12.

Accordingly, in the heat conduction structure 10, the buffer between the heat conducting base 11 and the heat diffusion plate 12 may be increased through the arrangement of the elastic element 40, so as to avoid a large relative displacement between the heat conducting base 11 and the heat spreading plate 12 under an external force and enhance the anti-vibration effect of the heat conduction structure 10.

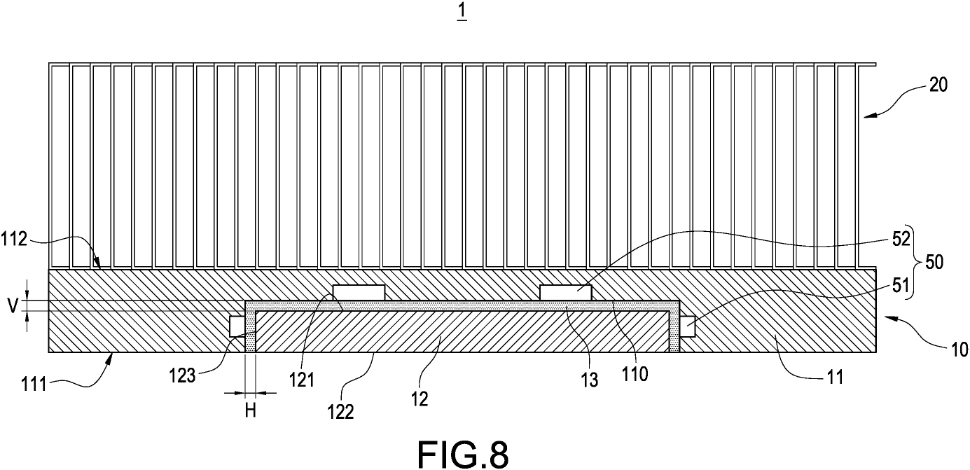

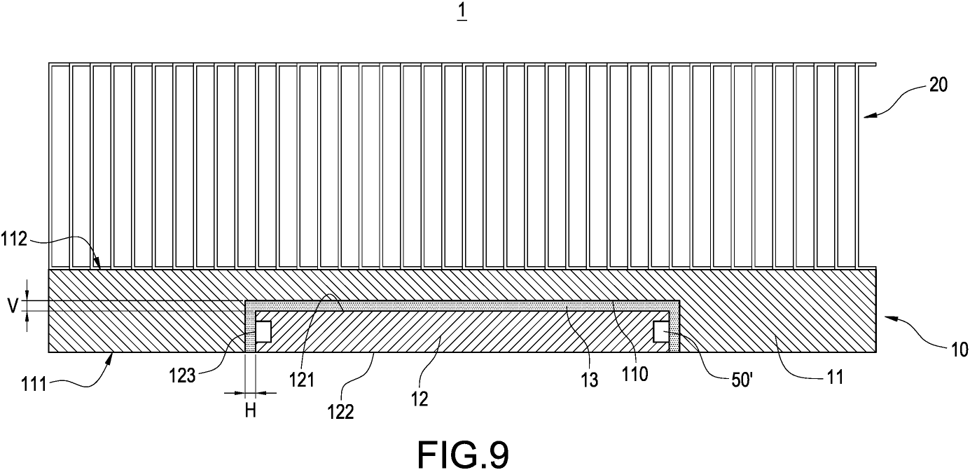

Please further refer to FIG. 8 and FIG. 9, they respectively depict cross sectional views of another embodiment of the heat dissipation device with the anti-vibration heat conduction structure in this disclosure. This embodiment is similar to the embodiment of FIG. 1, and the difference is that the inner wall surface of the accommodating slot 110 of the heat conduction structure 10 in this embodiment is recessed with at least one deformation space 50 communicating with the lateral gap H. The at least one deformation space 50 is used for accommodating excess thermal interface material 13 or the deformed thermal interface material 13.

As shown in FIG. 8, the deformation space 50 is arranged in a manner of a plurality of recesses, the deformation space 50 includes a lateral deformation space 51 facing the anti-vibration surface 123 of the heat diffusion plate 12 and a vertical deformation space 52 facing the inner conducting surface 121 of the heat diffusion plate 12.

Moreover, please refer to FIG. 9, the heat conducting structure 10 is recessed with at least one deformation space 50′ communicating with the lateral gap H on the anti-vibration surface 123 of the heat diffusion plate 12.

While this disclosure has been described by means of specific embodiments, numerous modifications and variations could be made thereto by those skilled in the art without departing from the scope and spirit of this disclosure set forth in the claims.

What is claimed is:

1. A heat conduction structure, comprising:
a heat conducting base, comprising a heat-absorbing side and a heat-emitting side opposite to each other, wherein an accommodating slot is defined concavely on the heat-absorbing side;
a heat diffusion plate, movably disposed in the accommodating slot, and comprising an inner conducting surface thermally connected to the heat conducting base, an outer conducting surface thermally connected to a heating element and at least one anti-vibration surface, wherein the at least one anti-vibration surface is respectively connected to the inner conducting surface and the outer conducting surface, and a lateral gap is reserved between the at least one anti-vibration surface and an inner wall surface of the accommodating slot; and
a thermal interface material, filled in the lateral gap between the at least one anti-vibration surface and the accommodating slot, wherein the heat diffusion plate and the heat conducting base are free from contacting each other through the thermal interface material under an external force.

2. The heat conduction structure according to claim 1, wherein the heat conducting base and the heat diffusion plate are respectively composed of a solid copper plate, a solid aluminum plate, a vapor chamber, or a flat heat pipe.

3. The heat conduction structure according to claim 1, wherein the thermal interface material comprises a thermal conductive paste or a thermal conductive silicone.

4. The heat conduction structure according to claim 1, wherein a vertical gap is reserved between the inner conducting surface and the inner wall surface of the accommodating slot, and the thermal interface material is filled in the vertical gap between the inner conducting surface and the heat conducting base.

5. The heat conduction structure according to claim 1, wherein a size of the lateral gap is about 0.5 mm to about 1.0 mm.

6. The heat conduction structure according to claim 1, further comprising: a seal ring, disposed between the heat conducting base and the heat diffusion plate and configured to seal the lateral gap.

7. The heat conduction structure according to claim 1, further comprising: an elastic element, connected between the heat conducting base and the heat diffusion plate, wherein one end of the elastic element is connected to the inner wall surface of the accommodating slot, and another end of the elastic element is connected to the inner conducting surface of the heat diffusion plate.

8. The heat conduction structure according to claim 1, wherein at least one deformation space is defined concavely on the inner wall surface of the accommodating slot and communicates with the lateral gap.

9. The heat conduction structure according to claim 1, wherein at least one deformation space is defined concavely on the at least one anti-vibration surface of the heat diffusion plate and communicates with the lateral gap.

10. A heat dissipation device, the heat dissipation device comprising:
a heat conduction structure according to claim 1; and
a heat conductor, thermally connected to the heat-emitting side and combined with the heat conducting base.

11. The heat dissipation device according to claim 10, wherein the heat conducting base and the heat diffusion plate are respectively composed of a solid copper plate, a solid aluminum plate, a vapor chamber or a flat heat pipe.

12. The heat dissipation device according to claim 10, wherein the thermal interface material comprises a thermal conductive paste or a thermal conductive silicone.

13. The heat dissipation device according to claim 10, wherein a vertical gap is reserved between the inner conducting surface and the inner wall surface of the accommodating slot, and the thermal interface material is filled in the vertical gap between the inner conducting surface and the heat conducting base.

14. The heat dissipation device according to claim 10, wherein a size of the lateral gap is about 0.5 mm to about 1.0 mm.

15. The heat dissipation device according to claim 10, further comprising: a seal ring, disposed between the heat conducting base and the heat diffusion plate and configured to seal the lateral gap.

16. The heat dissipation device according to claim 10, further comprising: an elastic element, connected between the heat conducting base and the heat diffusion plate, wherein one end of the elastic element is connected to the inner wall surface of the accommodating slot, and another end of the elastic element is connected to the inner conducting surface of the heat diffusion plate.

17. The heat dissipation device according to claim 10, wherein at least one deformation space is defined concavely on the inner wall surface of the accommodating slot and communicates with the lateral gap.

18. The heat dissipation device according to claim 10, wherein at least one deformation space is defined concavely on the at least one anti-vibration surface of the heat diffusion plate and communicates with the lateral gap.
